(19) United States
(12) Patent Application Publication
(10) Pub. No.: US 2019/0067502 A1
(43) Pub. Date: Feb. 28, 2019

(54) Flexible solar panel system built into Existing Products and into recycled materials

(71) Applicant: Dave Mashayamombe, Indianapolis, IN (US)

(72) Inventor: Dave Mashayamombe, Indianapolis, IN (US)

(21) Appl. No.: 16/111,988

(22) Filed: Aug. 24, 2018

Related U.S. Application Data
(60) Provisional application No. 62/550,552, filed on Aug. 25, 2017.

(51) Int. Cl. H01L 31/0445; H02S 30/20; H02S 20/20; A41G 1/00

(52) U.S. Cl. CPC H01L 31/0445; H02S 30/20; H02S 40/38; A41G 1/007; H02S 20/20

(57) ABSTRACT

An improved flexible solar panel system built into existing products and into recycled materials, the system provides a renewable energy source from the sun and a recyclable structure made from used tires and or plastic. The system is made using a flexible solar cell and panel collector, a battery, a light source, a structure to support all the components and conductors between the battery, the solar cell and the light source and battery.

### CROSS-REFERENCE TO RELATED APPLICATIONS

This application claims the benefit of U.S. Provisional Patent Application with Ser. No. 62/550,552 filed Aug. 25, 2017, by Dave Mashayamombe and entitled “An Improved Flexible solar panel system built into Existing Products and into recycled materials”.

### FIELD OF INVENTION

This invention relates to an improved Flexible solar panel system built into Existing Products and into recycled materials. More particularly it relates to a solar cell, a solar module, a solar array, and network of solar arrays for generating electric power for commercial and residential use with a capability to connect with the electrical power utility grid. It relates to a solar power system to provide electrical power to structures, artificial plants, yard lights, and to Christmas and outdoor decorations than need electricity. In addition it relates to a support system specifically as an artificial or simulated life-sized palm trees, other vegetation shrubs and trees etc., which is manufactured from recycled tires, used plastics, used composite materials, used paper, and used cardboard pulp. Making of these palm trees utilize recycling of discarded tires, plastics and paper into products that will substitute for

[symbol]

### FEDERALLY SPONSORED RESEARCH

None.

### SEQUENCE LISTING OR PROGRAM

None.

### BACKGROUND

### Field of Invention and Prior Art

As far as known, there is no Flexible solar panel system built into Existing Products and into recycled materials or the like that resembles life-sized vegetation. This is believed to be a unique system of energy recovery and transformation.

### Background

The world's present population is over six billion, and it is projected that by the year 2020 it will grow to over nine billion persons. Worldwide power consumption in 1997 was approximately 380 quadrillion British thermal units (Btu), and in response to the projected growth in population and industry the demand for power is expected to grow to about 608 quadrillion Btu by the year 2020. Likewise, worldwide consumption of oil is presently over 75 million barrels per day, and demand is expected to grow to about 120 million barrel per day by the year 2020. The world's oil reserves are estimated to be approximately 1,027 billion barrels. Fossil fuels such as coal, gas, and oil are non-renewable resources, and the burning of these fuels results in pollution of the earth's atmosphere, land, and water. Further, the burning of various fossil fuels may contribute to global warming and dramatic changes in climate, thus mankind is presently faced with an environmental catastrophe. Various alternate means of producing power such as hydrogen cells are presently being developed for use. However, even the burning of a non-fossil fuel such as hydrogen can possibly contribute to the problem of global warming. The United States and other industrialized nations of the world are still largely dependent upon internal combustion engines for transportation which consume gasoline or diesel fuel. Accordingly, the demand for a renewable and environmentally friendly source of power is one of the foremost needs and problems facing mankind.

Moreover, the creation of power generating facilities have sometimes compromised aesthetics and had other adverse environmental impacts. Dams have sometimes restricted the navigation of waterways and adversely affected fish populations such as salmon in the Pacific Northwest region of the United States. Nuclear power stations have been associated with radiation leaks, pollution, and the production of hazardous radioactive waste, whereas coal, oil and gas burning power stations are associated with more conventional forms of pollution. The installation of poles including overhead transmission lines alongside roads can sometimes constitute a hazard for motorists and compromise aesthetics.

Substantially all of the energy required for the creation and maintenance of life on the earth was originally provided by the sun. Solar energy is renewable and environmentally friendly. Faced with population, energy, and pollution crises, mankind can take a lesson from nature. The evolution of trees and other natural foliage on earth has been such as to maximize their ability to collect sunlight and perform photosynthesis. The present invention is directed towards providing renewable solar energy using solar arrays which resemble and emulate some of the light gathering abilities of natural foliage. In the words of Thomas Aquinas, “Grace does not abolish nature but perfects it.”

In addition, it has been estimated that roughly 3 billion discarded tires from automobiles and trucks litter the American landscape, and 200 million more are discarded every year. Most discarded tires sit in open dumps, where they collect rainwater and serve as breeding grounds for mosquitos, rats, and other pests.

### PROBLEMS SOLVED

Solar power to various products and structures that is aesthetically decorative to the products and structures and, if desired, can connect to utility grids. One of the present challenges and unanswered questions in the field of solar energy concerns how to make solar arrays and other solar systems that can provide environmentally green electrical energy and power comprising a structure which is also aesthetically pleasing so as to be desirable for installation in close proximity to residential homes, businesses, parking areas and also alongside streets, and highways. In this regard, solar arrays resembling palm trees which can provide electrical energy, and further comprise wireless transmission devices for the recharging and powering electrical devices including electric and hybrid transportation vehicles can provide a viable solution.

The other problem addressed with the discarded tires is to provide solar street lighting and an environmentally sustainable, permanent disposal of solid waste tires into a product for harnessing renewable energy.

### PRIOR ART

For the Flexible solar panel system built into Existing Products and into recycled materials, a novelty search was accomplished. It revealed, as far as known, there are no Flexible solar panel system built into Existing Products nor into recycled materials or the like. It is believed that this product is unique in its design and technologies.
A. A U.S. Pat. No. 5,094,905 by Murray was issued in 1992 for Structural articles made of recycled rubber fragments from tires. This invention relates to three dimensional members made from rubber fragments obtained from discarded tires. These items can be used as structural articles such as landscaping ties, dock bumpers for boat docks or truck loading docks, as resilient mats for workers or certain types of farm animals, or as substitutes for various products that are normally made of wood but which do not need to withstand large longitudinal loads. These articles are made by cutting, grinding, or shredding discarded tires into fragments. The fragments are mixed with an adhesive and molded, preferably under pressure, into a shape such as a rectangular beam. If desired for a particular use, these articles can be reinforced with strips of rubber or strands of fiber to give them greater tensile strength, or with reinforcing bars to give them added stiffness. If desired, they can be covered by a material such as plastic, impregnated cardboard, or a waterproof layer of adhesive.
B. A U.S. Pat. No. 5,316,708 by Drews was issued in 1994 for Method for making products made from recycled vehicle tires. This shows a process of making building block members by mixing natural latex with shredded vehicle tires to form a mixture, placing the mixture in a mold, applying pressure to compress the mixture, and maintaining pressure for a time period during which the latex hardens and cures.
C. A French patent FR2839991 by Urtiti was issued in 2002 for Wind break for halting advance of desert sands. It comprises staggered rows of artificial trees made from recycled plastics and used tyres. Here is shown a wind break consists of artificial trees made from recycled plastics and other materials, designed to simulate local trees such as palms. Each tree has a base that is buried in the ground, a trunk made from one or more pipe sections filled with sand, and a top with holes for inserting artificial palm leaves or branches. The trunk sections can be cut in half lengthwise for ease of transport and held together when assembled with the aid of used tyres.

D. A U.S. Pat. No. 5,787,649 by Popowych et al., was issued in 1998 for a Tree styled monopole tower. It demonstrates a modified monopole tower is described, consisting primarily of a galvanized steel truncated pyramidal monopole capped by wireless electronic communications antennae and equipment. In the preferred embodiment, the simulated trunk containing the monopole exhibits protruding receptors which in turn support artificial palm fronds, and artificial pine boughs and branches. The artificial palm fronds, branches, and boughs are attached to the receptors primarily by mechanical and adhesive means. The modified monopole tower is designed to function optimally under all weather conditions, while imitating the landscape with attachment of indigenous tree components.
E. A U.S. Pat. No. 6,343,440 by Ayres was issued in 2002 for Antenna towers having a natural appearance. It shows a monopole tower with antennas mounted near the top thereof is configured as either a tree such as a palm, or a pine, or other variety of tree having foliage that emulates that of natural trees so that the tower blends inconspicuously into the local surroundings. In the palm tree embodiment, one or more frond mounting assemblies encircle the monopole tree trunk, and include a plurality of receivers for holding palm fronds that are oriented at different angles relative to the monopole trunk. Individual fronds are made up of frond leaflets that are positioned along a frond spine member to closely emulate the appearance of a natural palm frond.
F. A U.S. Patent Application No. 2004/0011346 by Sakai was submitted in 2004 for a Decorative palm patio heater. Here is provided a patio heater with an outer shrouding of the functional upright fuel line formed to resemble the trunk of a palm tree, with an access means to reach the control but otherwise keep them from sight, and with a secondary heat distribution shield topped by decorative metal leaves resembling the leaves of a palm tree distributed in a balanced fashion around the circular trunk, embodies a functional aesthetic that will keep it both on display and in use in more circumstances than traditional, bare-bones functional patio heaters.

G. A U.S. Patent Application No. 2006/0185233 by Sporta was submitted in 2006 for a decorative structural supports. This invention shows a process for making a support member having a rigid elongate body formed of a member material comprising a plastics material and an outer surface comprising a plurality of non-longitudinal surface portions defining raised ridges outstanding from said member, said process comprising extruding said plastics material at a melt temperature through a die orifice at a selected extrusion rate and die orifice temperature to produce an extruded profile having an outer surface, the improvement comprising said extrusion rate and die orifice temperature being selected as to cause said outer surface to continuously, consistently and intermittently adhere to and be released from the die as defined by the stick-slip effect to form a desired plurality of scallop, wave-like ridges of uniform constant inter-ridge distance and essentially uniform height on said surface. The process provides a support member having a rigid elongate body formed of a member material comprising a plastics material and an outer surface comprising a plurality of non-longitudinal surface portions defining raised ridges outstanding from said member of use as a support structure, particularly, for plants, ornamental and other garden structures.
H. A U.S. Patent Application No. 2005/0045224 by Lyden was submitted in 2005 for a Solar cell, module, array, network, and power grid. The present invention teaches a solar cell, a solar module, a solar array, a network of solar arrays, and also a solar power grid suitable for providing power for industrial, residential and transportation use. A solar cell or solar module including a plurality of solar cells can be made in a structure configured to have the appearance of natural foliage. Accordingly, a solar array including a plurality of solar modules each including at least one solar cell can be made to resemble a palm tree, a deciduous tree, an evergreen tree, or other type of natural foliage. A network of solar arrays can be made to resemble a row or grove of palm trees, and thus meet the functional and aesthetic demands of landscape architecture. The network of solar arrays can extend for many miles alongside roads, highways, railways, pipelines, or canals, and can further include means for storing and transmitting electric power. In particular, a network of solar arrays can be in communication with recharging stations for use by electric and hybrid transportation vehicles. Accordingly, a network of solar arrays can form at least a portion of a solar power grid.
I. A U.S. Pat. No. 5,085,900 by Hamlett was issued in 1992 for an artificial palm tree. This portrays and demonstrates an artificial palm tree apparatus comprises a trunk, having a cylindrically shaped axial cavity, a cylindrically shaped cap having a plurality of cylindrically shaped ferrules rigidly secured to the outer cylindrical surface of the cap such that the axis of each of the ferrules is substantially parallel-ly aligned with the axis of the cap, a plurality of fronds, and a support tube. The trunk is constructed of long strips of glass fibers embedded in hardened resin. Each of the fronds is constructed of a rod and a plurality of artificial leaves spaced along the rod and secured thereto with an all-weather tape. One of each of the fronds is inserted through one of the ferrules and rigidly secured thereto by tightening a pair of nuts on a threaded end of a respective rod against opposite ends of the respective ferrule. The trunk is installed by embedding a portion of the support tube in the ground and telescoping the trunk cavity over the portion of the support tube extending upwardly from the ground. The cap with fronds secured thereto is telescoped over the upper end of the trunk. A first modified embodiment of the artificial palm tree apparatus has a trunk which is sectioned and one or more couplings for connecting the sections together during installation. A second modified embodiment of the artificial palm tree apparatus has a cap having a plurality of non-cylindrically shaped receivers, each of which operably receives a smaller, similarly shaped insert member rigidly secured to the base end of a respective frond.
J. A U.S. Patent Application No. 2013/0088858/8,684,551 by Alsaffar was submitted in 2013 for a Lighting assembly in the form of a palm tree. Provided here is a lighting assembly in the form of a palm tree as a decorative and ornamental street light includes an upwardly extending shaft, a base and a mechanism for fixing and anchoring the shaft in a selected location. The base includes a plurality of downwardly extending rods and a mass of concrete around and in between the rods to anchor the assembly. The upwardly extending shaft also includes a bark like outer cover and a plurality of outwardly extending limbs in the form of a palm tree. A plurality of lights illuminating an area around the assembly, the tree limbs including fronds
K. A U.S. Pat. No. 6,599,591 by Scott was issued in 2003 for a Flexible artificial tree and methods of making same. This teaches an artificial palm tree having a planar base, a central support, an exterior covering and a separable crown. The central support of the artificial palm tree has one end flexibly affixed to the planar base. An exterior covering constructed around the central support is substantially greater in diameter than the central support and has the separable crown removably affixed to a free end of the central support.
L. A U.S. Patent Application No. 2012/0181973 by Lyden was submitted in 2012 for a solar array resembling natural foliage including means for wireless transmission of electric power. The present invention teaches a solar array, and also a network of solar arrays for providing energy for industrial, residential and transportation use. A solar array of the present invention can be made to resemble a palm tree, a deciduous tree, an evergreen tree, or other type of natural foliage, and meet the aesthetic demands of landscape architecture. A network of solar arrays can extend for many miles along transportation right of ways including, but not limited to, roads, highways, railways, pipelines, or canals, and can further include means for storing and transmitting energy. A solar array can include or be coupled with a recharging station for use by electric and hybrid transportation vehicles. Moreover, an individual solar array or network of solar arrays can include means for wireless communication and transmission of energy for recharging an energy storage device and provide energy to an electric or hybrid transportation vehicle.

### SUMMARY OF THE INVENTION

This invention is an improved Flexible solar panel system built into Existing vegetation look alike Products and into recycled materials, the system is comprised of: (a) a flexible photo voltaic solar cell and energy collector, made of a durable material and used to produce electricity; (b) a battery to store the electric power; (c) a light source; (d) a first conductor connected at one end to the solar cell and the other end connected to the battery; (e) a second conductor connected at one end to the light source and the other end connected to the battery; and (f) a structure supporting the solar cell as an energy collector, the battery, the light source, the first conductor and the second conductor wherein the flexible solar panel system provides renewable energy to be used with different devices. Other embodiments are shown and claimed.

The newly invented and improved Flexible solar panel system built into Existing Products and into recycled materials can be manufactured at low volumes by very simple means and in high volume production by more complex and controlled systems.

### OBJECTS AND ADVANTAGES

There are several advantages of the Flexible solar panel system built into Existing Products and into recycled materials.

| No. | Advantage |
|---|---|
| 1 | Provides affordable supplementary renewable |
| | electricity for both domestic and commercial |
| | requirements. |
| 2 | Provides Energy savings for various lighting |
| | installations and electricity requirement |
| | using local solar power to supplement or |
| | replace electrical power from a utility grid. |
| 3 | Supports Environmental projects by |
| | economically using recycled tires, used |
| | plastic, used composite materials, used |
| | paper, and used cardboard pulp. |
| 4 | Provides an environmentally sustainable |
| | permanent disposal of solid waste tires, |
| | plastic and other non-biodegradable products |
| | into a product for harnessing renewable |
| | energy. |
| 5 | Product is aesthetically decorative to both |
| | city infrastructure and domestic landscaping. |
| 6 | Eliminates potentially unsafe electrical |
| | overhead lines for decorations and other |
| | outside lighting. |

Finally, other advantages and additional features of the present Flexible solar panel system built into Existing Products and into recycled materials will be more apparent from the accompanying drawings and from the full description of the device. For one skilled in the art of lighting devices especially ones incorporated into recycled materials or into other existing products, it is readily understood that the features shown in the examples with this configured product and device are readily adapted to other types of solar lighting systems and the like.

### DESCRIPTION OF THE DRAWINGS—FIGURES

The accompanying drawings, which are incorporated in and constitute a part of this specification, illustrate an embodiment of the improved Flexible solar panel system built into Existing Products and into recycled materials. The drawings together with the summary description given above and a detailed description given below serve to explain the principles of the improved Flexible solar panel system built into Existing Products and into recycled materials as a device for mounting and easily adjusting the solar power with a light onto existing products or with other recycled materials.

It is understood, however, that the Flexible solar panel system built into Existing Products and into recycled materials is not limited to only the precise arrangements and instrumentalities shown.

FIGS. 1 A through 1 E are sketches of the improved Flexible solar panel system built into Existing Products and into recycled materials, uses of the system and connection to the electrical grid.

FIGS. 2 A through 2 D are details and features of the improved Flexible solar panel system built into recycled materials.

FIGS. 3 A through 3 F are sketches of a thin and flexible photo voltaic solar cell and energy collector device and descriptions of its components and features.

FIGS. 4 A through 4 C are even more sketches of the Flexible solar panel system built into Existing Products and into recycled materials in use at a residential development and a shopping mall.

FIGS. 5 A and 5 B are sketches of the improved Flexible solar panel system built into Existing Products and into recycled materials in use at a residential development.

FIGS. 6 A through 6 D are sketches of other uses of the improved Flexible solar panel system built into Existing Products such as plants and decorations.

FIGS. 7 A through 7 E are sketches of other uses of the improved Flexible solar panel system built into Existing Products such as yard lights and structures with desired lighting.

FIGS. 8 A and 8 B are sketches to illustrate a system to connect an improved Flexible solar panel system to an electrical power grid.

FIGS. 9 A and 9 B are sketches of a process or method to provide improved Flexible solar panel system built with existing products, structures and appliances.

FIGS. 10 A through 10 C are sketches of a process or method to provide improved Flexible solar panel system built from recycled materials such as tire rubber or used plastic.

FIGS. 11 A through 11 D are sketches of prior art attempts to improve artificial trees and the like.

### DESCRIPTION OF THE DRAWINGS—REFERENCE NUMERALS

The following list refers to the drawings:

TABLE B
Reference numbers

| Ref # | Description |
|---|---|
| 30 | improved flexible solar panel system 30 built |
| | into existing Products and into recycled |
| | materials |
| 31 | improved flexible thin photovoltaic solar |
| | panel system 31 built into an artificial palm |
| | tree or the like |
| 32 | flexible thin photovoltaic solar panel system |
| | 32 built into an porch or yard lamp or small |
| | plants and trees |
| 33 | flexible thin photovoltaic solar panel system |
| | 33 built into an array of palm trees at a |
| | mall |
| 34 | flexible thin photovoltaic solar panel system |
| | 34 built into Christmas and outdoor |
| | decorations |
| 35 | flexible thin photovoltaic solar panel system |
| | 35 built into structures needing lights such |
| | as decks, gazebos and pergolas |
| 36 | flexible thin photovoltaic solar panel system |
| | 36 built into an array of artificial palm |
| | trees at a residential development |
| 40 | an array of artificial palm trees 40 (as an |
| | example and not a limitation) connected back |
| | to a bank of batteries 44 and controlled to |
| | an electrical utility grid 47 |
| 40A | an individual micro system 40A to handle one |
| | small conversion load at a time such a one |
| | (1) tree 31 or one (1) outdoor decoration 34 |
| 41 | sun power/source of energy 41 to solar cells |
| | and energy collectors 61 |
| 42 | charge controller 42 |
| 43 | individual battery 43 in bank 44 |
| 44 | battery bank 44 of grid connection system 40 |
| 45 | electrical power inverter 45 - direct current |
| | (DC) changed to alternating current (AC) |
| 45A | micro electrical power inverter 45A - direct |
| | current (DC) changed to alternating current |
| | (AC) for small quantities of electrical power |
| 46 | electrical power meter 46 |
| 47 | electrical power utility grid 47 |
| 48 | alternating current (AC) disconnect 48 |
| 49 | main power disconnect 49 |
| 50 | other loads 50 in an improved Flexible solar |
| | panel system |
| 60 | artificial palm tree fronds or leaves 60 |
| 61 | flexible thin photovoltaic solar cells and |
| | energy collectors 61 and energy collectors |
| | such as amorphous thin-film silicon (a-Si), |
| | cadmium telluride (CdTe), and copper indium |
| | gallium di-selenide (CIGS), and other |
| | photovoltaic, flexible and composite |
| | materials as they become more commercially |
| | feasible |
| 61A | reinforcing material 61A for CIGS sheets |
| 61B | CIGS chips 61B - small, thin - for micro |
| | systems |
| 62 | electrical conductors 62 from solar cells 61 |
| 63 | charge controller 63 to monitor individual |
| | battery 64 and when charged to preset load, |
| | permit excess electricity to flow to battery |
| | banks 44 and ultimately to a utility grid 47 |
| 64 | individual battery 64 at palm tree, light, |
| | decoration etc. |
| 65 | flexible thin photovoltaic solar bands (for |
| | larger installations and greater |
| | requirements) 65 such as amorphous thin-film |
| | silicon (a-Si), cadmium telluride (CdTe), and |
| | copper indium gallium di-selenide (CIGS), and |
| | other photovoltaic, flexible and composite |
| | materials as they become commercially |
| | feasible |
| 66 | electrical conductors 66 for excess |
| | electrical charge from individual appliance |
| | battery 64 and charge controller 63 to grid |
| | connection system 40 |
| 67 | light source 67 such as, for example and not |
| | limitation, light emitting diodes (LED), |
| | fluorescent, incandescent, halogen, mercury |
| | vapor, etc. |
| 68 | brace/extension arm structure 68 from |
| | trunk/vertical structure 69 for supporting |
| | light source 67 |
| 69 | trunk/vertical structure 69 |
| 70 | short tube segments 70 to form trunk/ |
| | vertical structure 69 |
| 71 | longer tube segments 71 to form trunk/ |
| | vertical structure 69 |
| 72 | removable means for connecting securely 72 |
| | the segments 70, 71 of the trunk/vertical |
| | structure 69 |
| 73 | threaded interlock 73 to removably secure the |
| | segments 70, 71 of the trunk/vertical |
| | structure 69 |
| 74 | slip fit interlock 74 (with pins or adhesive) |
| | to secure the segments 70, 71 of the trunk/ |
| | vertical structure 69 |
| 75 | separate piece interlock 75 (with pins or |
| | adhesive) to secure the segments 70, 71 of |
| | the trunk/vertical structure 69 |
| 76 | foundation/base 76 for artificial palm tree |
| | system 31 |
| 80 | back sheet 80 for flexible thin photovoltaic |
| | solar cells 61 |
| 81 | photo voltaic coating 81 |
| 82 | connector 82 from conductor 83 of flexible |
| | thin photo voltaic solar cells 61 |
| 83 | conductor 83 from connector 82 and flexible |
| | thin photovoltaic solar cells 61 to battery |
| | 64 or charge controller 63 |
| 84 | CIGS photo voltaic cross section 84 |
| 85 | interconnect electrical diagram 85 |
| 91 | kit 91 of components for adding the flexible |
| | thin photo voltaic solar system 30 to |
| | existing products and structures |
| 92 | process of adding 92 the flexible thin photo |
| | voltaic solar 30 to existing products |
| | 93, 32, 35 |
| 93 | example products 93 |
| 94 | sample lighting 94 of example products 93 at |
| | night |
| 95 | recycled tires (and used plastic, used |
| | composite materials, used paper, and used |
| | cardboard pulp) 95 |
| 96 | human activity 96 generating recycled tires |
| | 95 |
| 97 | municipal disposal issue or problem 97 |
| 98 | system 98 to flexible thin photo voltaic |
| | solar system 61 with palm trees 31 |
| 100 | human 100 as size reference |
| 101 | human thumb 101 as size reference |
| 110 | prior art 110 is U.S. Pat. No. 5,089,900 entitled |
| | Artificial Palm Tree |
| 111 | prior art 111 is US Patent Application |
| | 2006/0185233 entitled Decorative Structural |
| | Supports |
| 112 | prior art 112 is U.S. Pat. No. 6,599,591 entitled |
| | Flexible Artificial Tree and Methods of |
| | Making Same |
| 113 | prior art 113 is U.S. Pat. No. 8,684,551 entitled |
| | Ornamental Lighting Assembly |
| 113A | segmented trunk 113A in prior art 113 is U.S. |
| | Pat. No. 8,684,551 |

### DETAILED DESCRIPTION OF PERFERRED EMBODIMENT

The present development is a Flexible solar panel system built into Existing Products and into recycled materials. More particularly it relates to a solar cell, a solar module, a solar array, and network of solar arrays for generating electric power for commercial and residential use with a capability to connect with the electrical power utility grid. It relates to a solar power system to provide electrical power to structures, artificial plants, yard lights, and to Christmas and outdoor decorations than need electricity. In addition it relates to a support system specifically as an artificial or simulated life-sized palm trees palm trees that is manufactured from recycled tires, used plastic, used composite materials, used paper, and used cardboard pulp. Making of these palm trees utilize recycling of discarded tires into products that will substitute for artificial palm trees and simulated flora.

The advantages for the Flexible solar panel system built into Existing Products and into recycled materials are listed above in the introduction. Succinctly these are:
a) Provides affordable supplementary renewable electricity for both domestic and commercial requirements;
b) Provides Energy savings for various lighting installations and electricity requirement using local solar power to supplement or replace electrical power from a utility grid;
c) Supports Environmental projects by economically using recycled tires, used plastic, used composite materials, used paper, and used cardboard pulp;
d) Provides an environmentally sustainable permanent disposal of solid waste tires into a product for harnessing renewable energy;
e) Product is aesthetically decorative to both city infrastructure and domestic landscaping; and
f) Eliminates potentially unsafe electrical overhead lines for decorations and other outside lighting.
   These advantages will be better understood once the description and operation is viewed.

The preferred embodiment of this invention is an improved Flexible solar panel system built into Existing Products and into recycled materials, the system is comprised of: (a) a flexible photo voltaic solar cell and energy collector, made of a durable material and used to produce electricity; (b) a battery to store the electric power; (c) a light source; (d) a first conductor connected at one end to the solar cell and the other end connected to the battery; (e) a second conductor connected at one end to the light source and the other end connected to the battery; and (f) a structure supporting the solar cell, the battery, the light source, the first conductor and the second conductor wherein the flexible solar panel system provides renewable energy to be used with different devices. Other embodiments are shown and claimed.

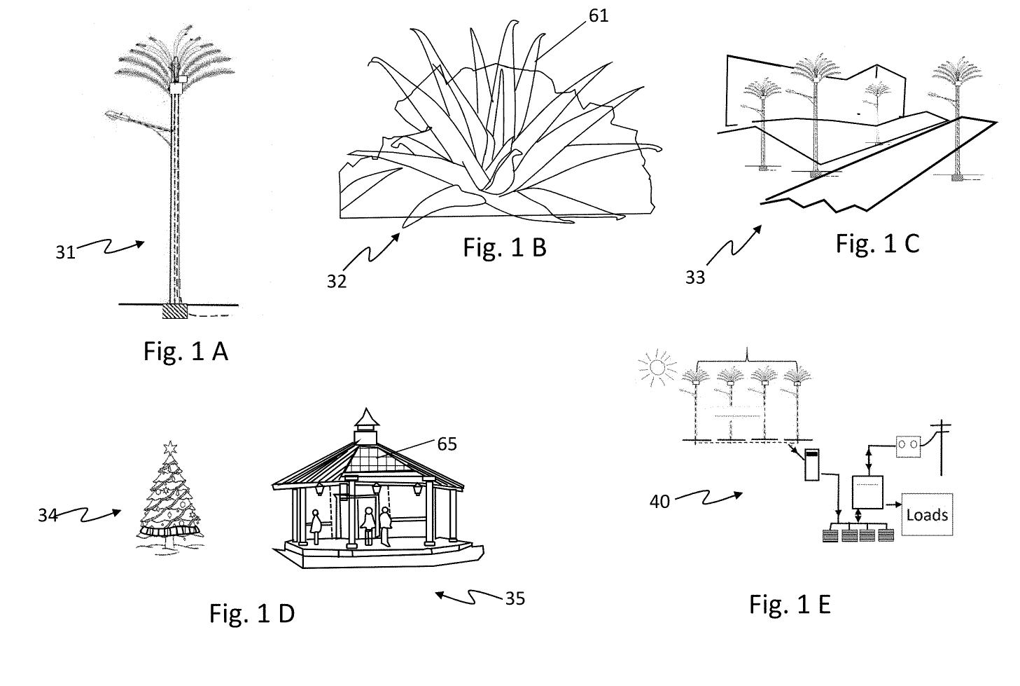

There is shown in FIGS. 1-11 a complete description and operative embodiment of the improved Flexible solar panel system 30 built into Existing Products and into recycled materials. In the drawings and illustrations, one notes well that the FIGS. 1-11 demonstrate the general configuration and use of this product. The various example uses are in the operation and use section, below.

The accompanying drawings, which are incorporated in and constitute a part of this specification, illustrate an embodiment of the improved Flexible solar panel system 30 built into Existing Products and into recycled materials that is preferred. The drawings together with the summary description given above and a detailed description given below serve to explain the principles of the solar powered device 30. It is understood, however, that the solar powered device 30 is not limited to only the precise arrangements and instrumentalities shown. Other examples of solar power to other existing devices and structures or with recycled materials as devices and uses are still understood by one skilled in the art of solar power and thin photovoltaic systems to be within the scope and spirit shown here.

FIGS. 1 A through 1 E are sketches of the Flexible solar panel system 30 built into Existing Products and into recycled materials, uses of the system and connection to the electrical grid 47. Shown as an introduction in these sketches are: an improved flexible thin photovoltaic solar panel system 31 built into an artificial palm tree or the like; a flexible thin photovoltaic solar panel system 32 built into an porch or yard lamp or small plants and trees; a flexible thin photovoltaic solar panel system 33 built into an array of palm trees at a mall; a flexible thin photovoltaic solar panel system 34 built into Christmas and outdoor decorations; a flexible thin photovoltaic solar panel system 35 built into structures needing lights such as decks, gazebos and pergolas; an array of artificial palm trees 40 (as an example and not a limitation) connected back to a bank of batteries 44 and controlled to an electrical utility grid 47; a flexible thin photovoltaic solar cells and energy collectors 61 such as amorphous thin-film silicon (a-Si), cadmium telluride (CdTe), and copper indium gallium di-selenide (CIGS), and other photovoltaic, flexible and composite materials as they become commercially feasible; and a charge controller 63 to monitor individual battery 64 and when charged to preset load, permit excess electricity to flow to battery banks 44 and ultimately to a utility grid 47.

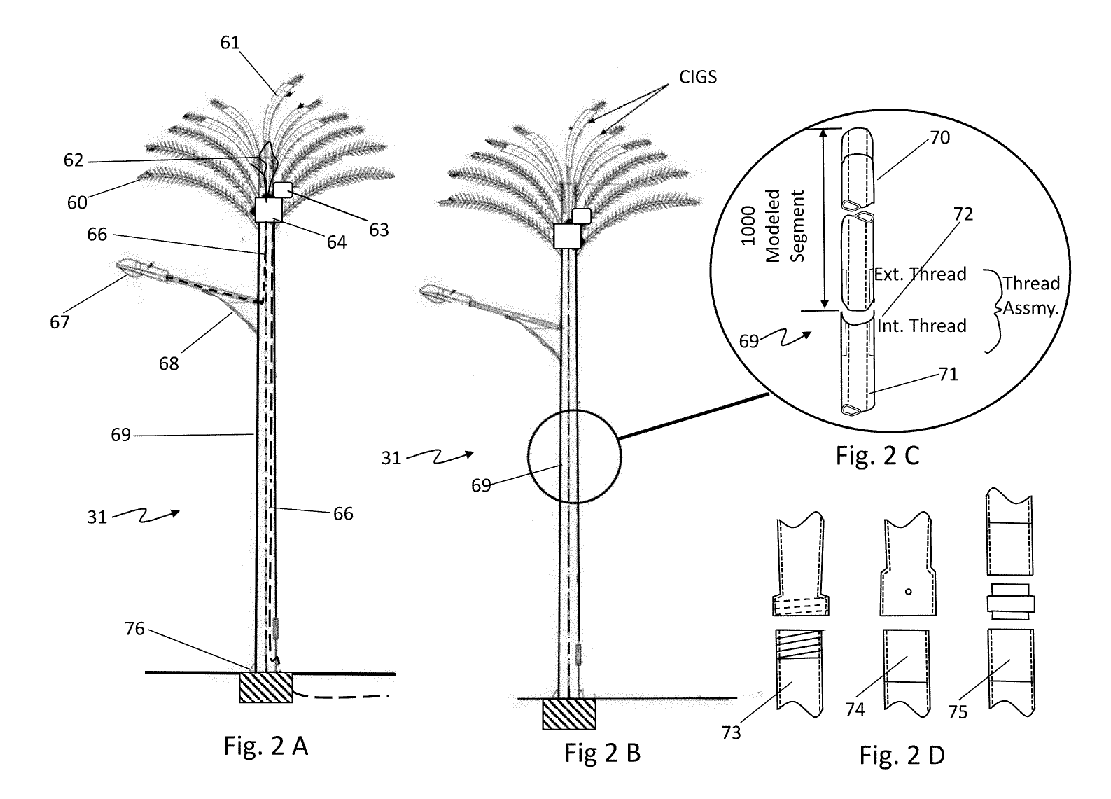

FIGS. 2 A through 2 D are details and features of the improved Flexible solar panel system 31 built recycled materials. In these sketches and drawings are demonstrated: an artificial palm tree fronds or leaves 60; a flexible thin photovoltaic solar cells and energy collectors 61 such as amorphous thin-film silicon (a-Si), cadmium telluride (CdTe), and copper indium gallium di-selenide (CIGS), and other photovoltaic, flexible and composite materials as they become commercially feasible; a reinforcing material 61A for CIGS sheets; CIGS chips 61B—small, thin—for micro systems; an electrical conductors 62 from solar cells 61; a charge controller 63 to monitor individual battery 64 and when charged to preset load, permit excess electricity to flow to battery banks 44 and ultimately to a utility grid 47; an individual battery 64 at palm tree, light, decoration etc.; a flexible thin photovoltaic solar bands (for larger installations and greater requirements) 65 such as amorphous thin-film silicon (a-Si), cadmium telluride (CdTe), and copper indium gallium di-selenide (CIGS), and other photovoltaic, flexible and composite materials as they become commercially feasible; an electrical conductors 66 for excess electrical charge from individual appliance battery 64 and charge controller 63 to grid connection system 40; a light source 67 such as, for example and not limitation, light emitting diodes (LED), fluorescent, incandescent, halogen, mercury vapor, etc.; a brace/extension arm structure 68 from trunk/vertical structure 69 for supporting light source 67; a trunk/vertical structure 69; a short tube segments 70 to form trunk/vertical structure 69; a longer tube segments 71 to form trunk/vertical structure 69; a removable means for connecting securely 72 the segments 70, 71 of the trunk/vertical structure 69; a threaded interlock 73 to removably secure the segments 70, 71 of the trunk/vertical structure 69; a slip fit interlock 74 (with pins or adhesive) to secure the segments 70, 71 of the trunk/vertical structure 69; a separate piece interlock 75 (with pins or adhesive) to secure the segments 70, 71 of the trunk/vertical structure 69; and a foundation/base 76 for artificial palm tree system 31. One can use plastic and/or rubber to mold the trees and flexible photovoltaic panels as broad leaf branches located at the top. These are the solar energy source converter for recharging the batteries 64 that power the lights source 67. Normally, only the top 4 branches are the energy source being flexible thin film solar panels 61. Each of the branches is made of one solid broad leaf/frond or picture a banana branch/leaf. The leaf will be a molded plastic onto which the flexible thin film panel is laminated using an adhesive. Thereby it takes the shape of the broad leaf branch. The tires can be molded from the tires as one piece or segmented pieces, etc. The materials for the tree now therefore includes the following: Reinforced fiber glass, recycled plastic, Perspex or other acrylic sheets or the like, recycled tire rubber and broadly any such material (recycled or virgin material) that can be molded to furnish resemblance of artificial vegetation. With respect to the segments—The taller trees can be molded as segments with a mating thread or other interlock means 72 that is then screwed one on top of another to build up the tree going vertically upwards. The shorter vegetation varieties can be molded as an integral piece.

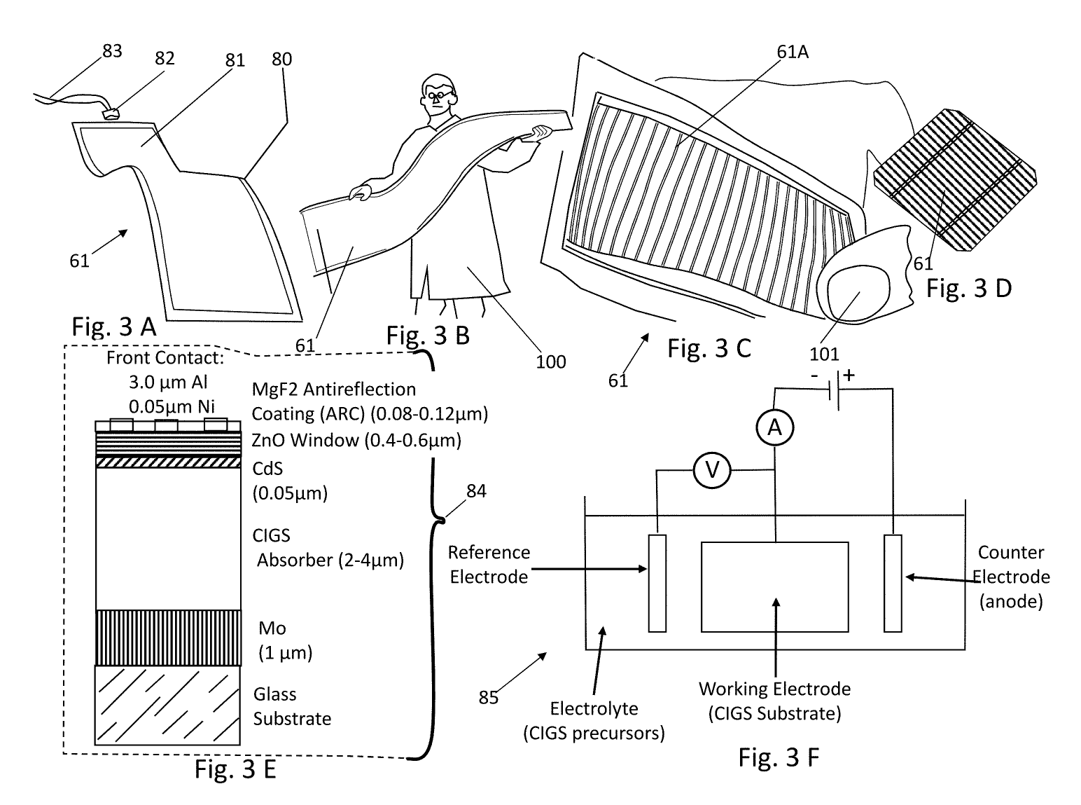

FIGS. 3 A through 3 F are sketches of a thin and flexible photo voltaic solar cell device and energy collectors 61 and descriptions of its components and features. Shown here are: a flexible thin photovoltaic solar cells 61 such as amorphous thin-film silicon (a-Si), cadmium telluride (CdTe), and copper indium gallium di-selenide (CIGS), and other photovoltaic, flexible and composite materials as they become commercially feasible; a reinforcing material 61A for CIGS sheets; CIGS chips 61B—small, thin—for micro systems; a back sheet 80 for flexible thin photovoltaic solar cells 61; a photo voltaic coating 81; a connector 82 from conductor 83 of flexible thin photo voltaic solar cells 61; a conductor 83 from connector 82 and flexible thin photovoltaic solar cells 61 to battery 64 or charge controller 63; a CIGS photo voltaic cell cross section 84; an interconnect electrical diagram 85; an interconnect electrical diagram 85; a human 100 as size reference; and a human thumb 101 as size reference. A CIGS is a compound semiconductor material composed of copper, indium, gallium, and selenium. The material is a solid solution of copper indium selenide (often abbreviated “CIS”) and copper gallium selenide, with a chemical formula of CuInₓGa₍₁₋ₓ₎Se₂, where the value of x can vary from 1 (pure copper indium selenide) to 0 (pure copper gallium selenide). It is a tetrahedrally bonded semiconductor, with the chalcopyrite crystal structure. The bandgap varies continuously with x from about 1.0 eV (for copper indium selenide) to about 1.7 eV (for copper gallium selenide). FIG. 3 E is a Structure of a CIGS device. A CdS is used optionally and some CIGS cells contain no cadmium at all. CIGS has an exceptionally high absorption coefficient of more than 10⁵/cm for 1.5 eV and higher energy photons. With CIGS solar cells have efficiencies around 20% have been claimed by the National Renewable Energy Laboratory (NREL), the Swiss Federal Laboratories for Materials Science and Technology (Empa), and the German Zentrum für Sonnenenergie und Wasserstoff Forschung (ZSW), which is the record to date for any thin film solar cell. The most common device structure for CIGS solar cells is shown in the diagram (see FIG. 3 E: Structure of a CIGS device). Soda-lime glass of about of 1-3 millimeteres thickness commonly used as a substrate, because the glass sheets contains sodium, which has been shown to yield a substantial open-circuit voltage increase, notably through surface and grain boundary defects passivation. However, many companies are also looking at lighter and more flexible substrates such as polyimide or metal foils. A molybdenum (Mo) metal layer is deposited (commonly by sputtering) which serves as the back contact and reflects most unabsorbed light back into the CIGS absorber. Following molybdenum deposition a p-type CIGS absorber layer is grown by one of several unique methods. A thin n-type buffer layer is added on top of the absorber. The buffer is typically cadmium sulfide (CdS) deposited via chemical bath deposition. The buffer is overlaid with a thin, intrinsic zinc oxide layer (i-ZnO) which is capped by a thicker, aluminum (Al) doped ZnO layer. The i-ZnO layer is used to protect the CdS and the absorber layer from sputtering damage while depositing the ZnO Al window layer, since the latter is usually deposited by DC sputtering, known as a damaging process. The Al doped ZnO serves as a transparent conducting oxide to collect and move electrons out of the cell and energy collector while absorbing as little light as possible. The CuInSe₂-based materials that are of interest for photovoltaic applications include several elements from groups I, III and VI in the periodic table. These semiconductors are especially attractive for solar applications because of their high optical absorption coefficients and versatile optical and electrical characteristics which can in principle be manipulated and tuned for a specific need in a given device.

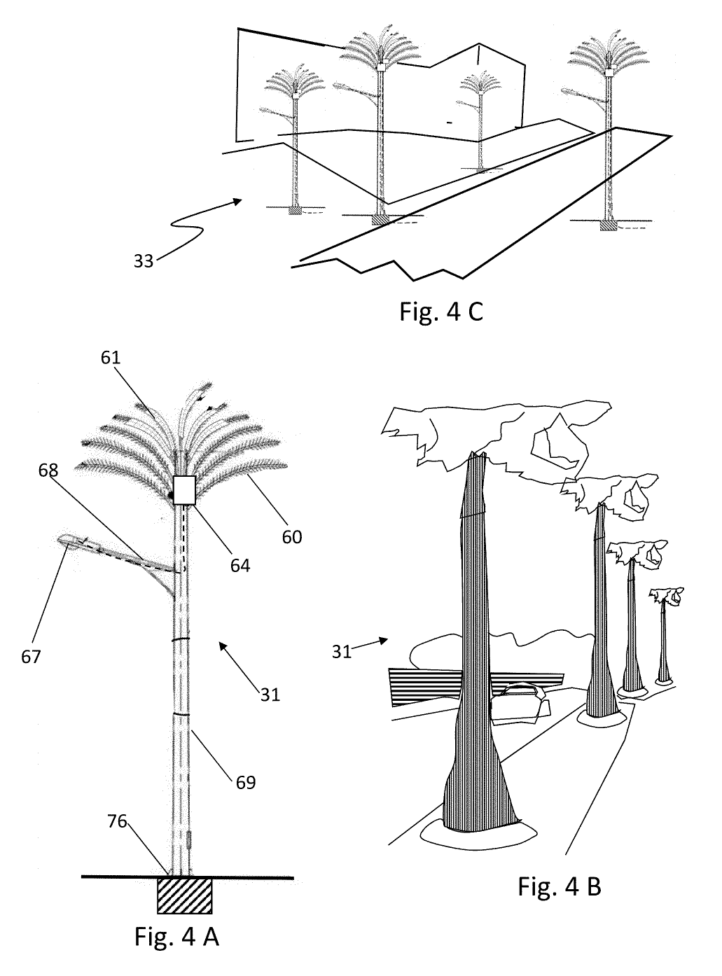

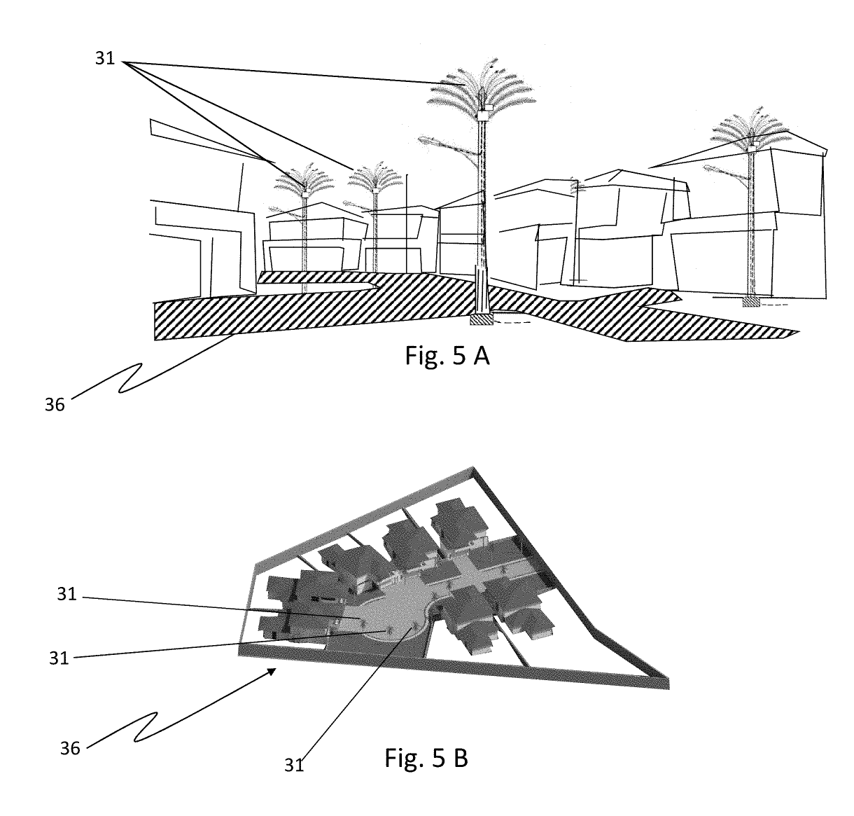

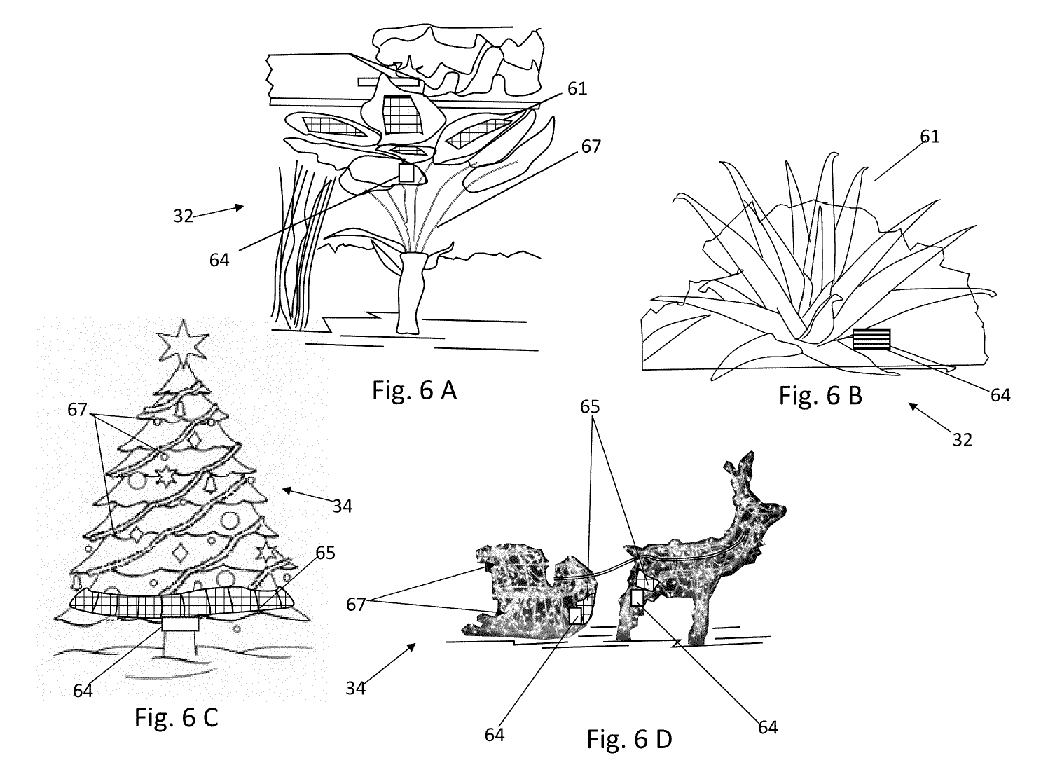

FIGS. 4 A through 4 C are even more sketches of the improved Flexible solar panel system built into Existing Products and into recycled materials in use at a residential development and a shopping mall. FIGS. 5 A and 5 B are sketches of the improved Flexible solar panel system built into Existing Products and into recycled materials in use at a residential development. FIGS. 6 A through 6 D are sketches of other uses of the improved Flexible solar panel system built into Existing Products such as plants and decorations. 7 A through 7 E are sketches of other uses of the Flexible solar panel system built into Existing Products such as yard lights and structures with desired lighting. These sketches are all described in the Operations Section.

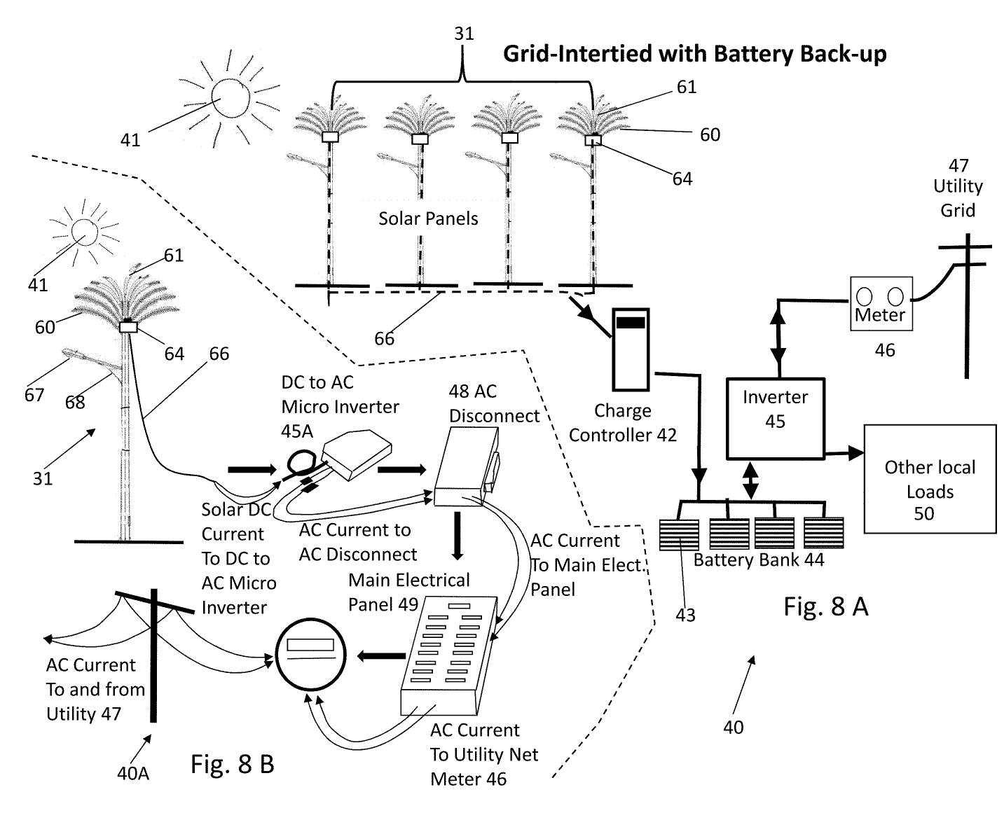

FIGS. 8 A and 8 B are sketches to illustrate a system 40 to connect an improved Flexible solar panel system to an electrical power grid 47. Provided here are: an improved flexible thin photovoltaic solar panel system 31 built into an artificial palm tree or the like; an array of artificial palm trees 40 (as an example and not a limitation) connected back to a bank of batteries 44 and controlled to an electrical utility grid 47; an individual micro system 40A to handle one small conversion load at a time such a one (1) tree 31 or one (1) outdoor decoration 34; a sun power/source of energy 41 to solar cells and energy collectors 61; a charge controller 42; an individual battery 43 in bank 44; a battery bank 44 of grid connection system 40; an electrical power inverter 45—direct current (DC) changed to alternating current (AC); a micro electrical power inverter 45A—direct current (DC) changed to alternating current (AC) for small quantities of electrical power; an electrical power meter 46; an electrical power utility grid 47; an alternating current (AC) disconnect 48; a main power disconnect 49; other loads 50 in an improved Flexible solar panel system; an artificial palm tree fronds or leaves 60; a flexible thin photovoltaic solar cells 61 such as amorphous thin-film silicon (a-Si), cadmium telluride (CdTe), and copper indium gallium diselenide (CIGS), and other photovoltaic, flexible and composite materials as they become commercially feasible; an individual battery 64 at palm tree, light, decoration etc.; a flexible thin photovoltaic solar bands (for larger installations and greater requirements) 65 such as amorphous thin-film silicon (a-Si), cadmium telluride (CdTe), and copper indium gallium di-selenide (CIGS), and other photovoltaic, flexible and composite materials as they become commercially feasible; an electrical conductors 66 for excess electrical charge from individual appliance battery 64 and charge controller 63 to grid connection system 40; a light source 67 such as, for example and not limitation, light emitting diodes (LED), fluorescent, incandescent, halogen, mercury vapor, etc.; and a brace/extension arm structure 68 from trunk/vertical structure 69 for supporting light source 67.

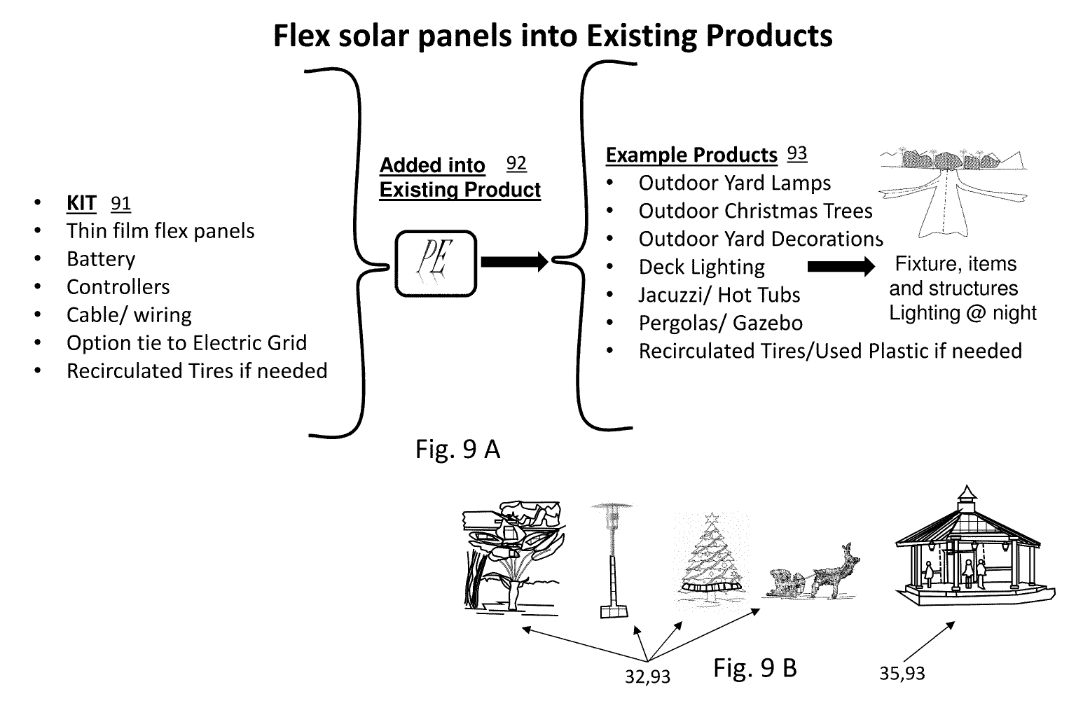

FIGS. 9 A and 9 B are sketches of a process or method to provide improved Flexible solar panel system built with existing products, structures and appliances. The method/process here depicts by the sketches: a flexible thin photovoltaic solar panel system 32 built into an porch or yard lamp or small plants and trees; a flexible thin photovoltaic solar panel system 35 built into structures needing lights such as decks, gazebos and pergolas; a kit 91 of components for adding the flexible thin photo voltaic solar system 30 to existing products and structures; a process of adding 92 the flexible thin photo voltaic solar 30 to existing products 93, 32, 35; an example products 93; and a sample lighting 94 of example products 93 at night.

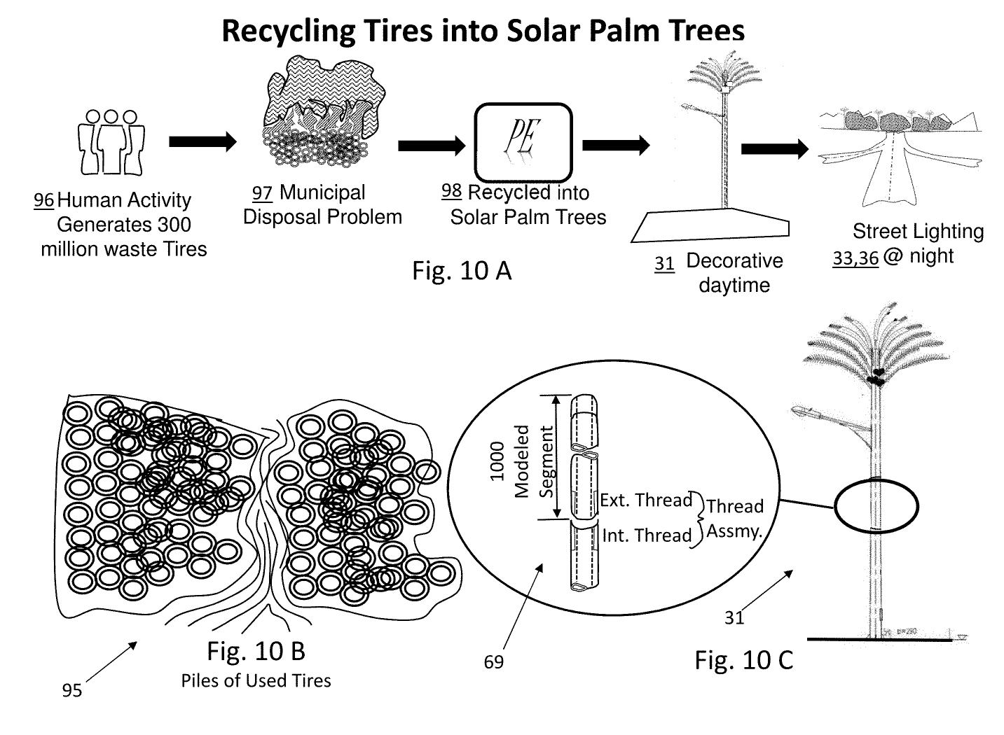

FIGS. 10 A through 10 C are sketches of a process or method to provide an improved Flexible solar panel system built from recycled materials such as tire rubber, used plastic, used composite materials, used paper, and used cardboard pulp. Here are shown the process as: an improved flexible thin photovoltaic solar panel system 31 built into an artificial palm tree or the like; a flexible thin photovoltaic solar panel system 33 built into an array of palm trees at a mall; a flexible thin photovoltaic solar panel system 36 built into an array of artificial palm trees at a residential development; a trunk/vertical structure 69; a recycled tires (and used plastic, used composite materials, used paper, and used cardboard pulp) 95; a human activity 96 generating recycled tires 95;

a municipal disposal issue or problem 97; and a system 98 to flexible thin photo voltaic solar system 61 with palm trees 31. Recycled tires represent globally=$3Billion and the USA estimated at $600 million in respect of the solid waste tire pollution problem. This does not just provide solar street lighting. It provides an environmentally sustainable permanent disposal of solid waste tires into a product for harnessing renewable energy. And the product is aesthetically decorative to city infrastructure. Only 30% of discarded tires are being recovered for reuse and recycling. A shocking 50% are incinerated in boilers as a ‘fuel’ (they call it Tire Derived Fuel). Everyone knows that burning tires—highly polluting to the air that one breathes. In nearly all U.S. States, the disposal of waste tires in landfills is prohibited. And, illegal dumping and stockpiling of tires mars the landscape and poses serious environmental problems for communities as well as breeding environment for rodents and disease bearing organisms like Mosquitoes. Palm Energy, Mashayamombe, and his support team together have created a NEW MARKET—a permanent & sustainable way of disposal of waste tires. The system: Provide a sustainable environmentally friendly road lighting solution to the very creators of the problem—the drivers; provides a new permanent disposal of solid waste tire to the municipalities; is an aesthetically decorative product to the road infrastructure; provides a new supply chain opportunities for existing industry; and provides new employment opportunities for the wider economy.

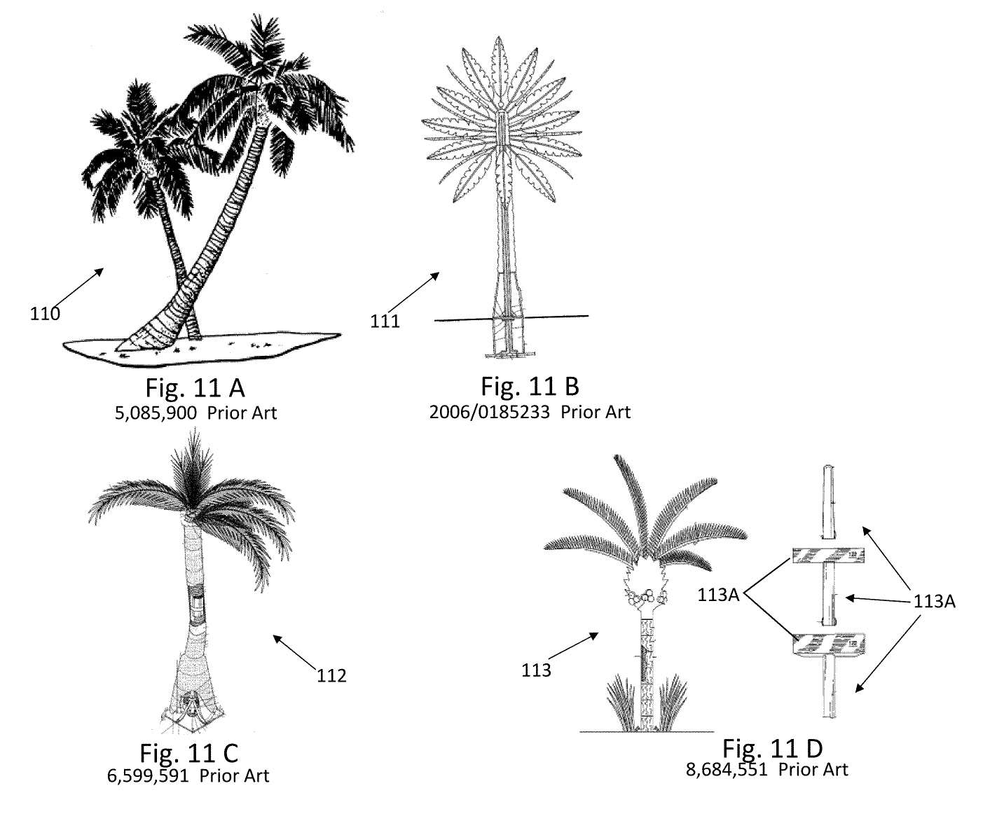

FIGS. 11 A through 11 D are sketches of prior art attempts to improve artificial trees and the like. Here former patents and applications for devices are shown. These include: the prior art 110 is U.S. Pat. No. 5,089,900 entitled Artificial Palm Tree; the prior art 111 is US Patent Application 2006/0185233 entitled Decorative Structural Supports; the prior art 112 is U.S. Pat. No. 6,599,591 entitled Flexible Artificial Tree and Methods of Making Same; the prior art 113 is U.S. Pat. No. 8,684,551 entitled Ornamental Lighting Assembly; and the segmented trunk 113A in prior art 113 is U.S. Pat. No. 8,684,551. As can be seen, the improved Flexible solar panel system 30 built into Existing Products and into recycled materials is a unique combination and use as described herein.

The details mentioned here are exemplary and not limiting. Other specific components and manners specific to describing an improved Flexible solar panel system 30 built into Existing Products and into recycled materials may be added as a person having ordinary skill in the field of the art of solar power and thin photovoltaic power systems, devices and their uses well appreciates.

### OPERATION OF THE PREFERRED EMBODIMENT

The Flexible solar panel system 30 built into Existing Products and into recycled materials has been described in the above embodiment. The manner of how the device operates is described below. One notes well that the description above and the operation described here must be taken together to fully illustrate the concept of the Flexible solar panel system 30 built into Existing Products and into recycled materials.

The preferred embodiment of this invention is a Flexible solar panel system built into Existing Products and into recycled materials, the system is comprised of: (a) a flexible photo voltaic solar cell and energy collector, made of a durable material and used to produce electricity; (b) a battery to store the electric power; (c) a light source; (d) a first conductor connected at one end to the solar cell and the other end connected to the battery; (e) a second conductor connected at one end to the light source and the other end connected to the battery; and (f) a structure supporting the solar cell, the battery, the light source, the first conductor and the second conductor wherein the flexible solar panel system provides renewable energy to be used with different devices. Other embodiments are shown and claimed.

FIGS. 4 A through 4 C are even more sketches of the improved Flexible solar panel system built into Existing Products and into recycled materials in use at a residential development and a shopping mall. These sketches depict: an improved flexible thin photovoltaic solar panel system 31 built into an artificial palm tree or the like; a flexible thin photovoltaic solar panel system 33 built into an array of palm trees at a mall; an artificial palm tree fronds or leaves 60; a flexible thin photovoltaic solar cells 61 such as amorphous thin-film silicon (a-Si), cadmium telluride (CdTe), and copper indium gallium di-selenide (CIGS), and other photovoltaic, flexible and composite materials as they become commercially feasible; an individual battery 64 at palm tree, light, decoration etc.; a brace/extension arm structure 68 from trunk/vertical structure 69 for supporting light source 67; a trunk/vertical structure 69; and a foundation/base 76 for artificial palm tree system 31.

FIGS. 5 A and 5 B are sketches of the Flexible solar panel system built into Existing Products and into recycled materials in use at a residential development. The features and components are discussed above in the Detailed Description. The uses here show: an improved flexible thin photovoltaic solar panel system 31 built into an artificial palm tree or the like and a flexible thin photovoltaic solar panel system 36 built into an array of artificial palm trees at a residential development. This street of eight (8) modern homes has four (4) Palm Solar Street Lights with decorative landscaping in daytime and street lighting at night. If each Household has two vehicles and each vehicle changes tires once every four (4) years, then eight (8) waste tires produced for that period. All eight (8) homes equal sixty-four (64) waste tires. Compare this with now each Palm Solar Tree being street lamp of residential size consumes about twenty (20) waste tires as recycled raw material. Four Street lamps will consume eighty (80) tires. This means the tire consumption of eight (8) households over four (4) years is Carbon Neutral. In fact it is Carbon Negative because eight (8) houses generate sixty-four (64) tires while the street lighting will require eighty (80) tires in raw material.

FIGS. 6 A through 6 D are sketches of other uses of the improved Flexible solar panel system built into Existing Products such as plants and decorations. Portrayed here are: a flexible thin photovoltaic solar panel system 32 built into an porch or yard lamp or small plants and trees; a flexible thin photovoltaic solar panel system 34 built into Christmas and outdoor decorations; a flexible thin photovoltaic solar cells and energy collectors 61 such as amorphous thin-film silicon (a-Si), cadmium telluride (CdTe), and copper indium gallium di-selenide (CIGS), and other photovoltaic, flexible and composite materials as they become commercially feasible; an individual battery 64 at palm tree, light, decoration etc.; a flexible thin photovoltaic solar bands (for larger installations and greater requirements) 65 such as amorphous thin-film silicon (a-Si), cadmium telluride (CdTe), and copper indium gallium di-selenide (CIGS), and other photovoltaic, flexible and composite materials as they become commercially feasible; a light source 67 such as, for example and not limitation, light emitting diodes (LED), fluorescent, incandescent, halogen, mercury vapor, etc.; and a trunk/vertical structure 69.

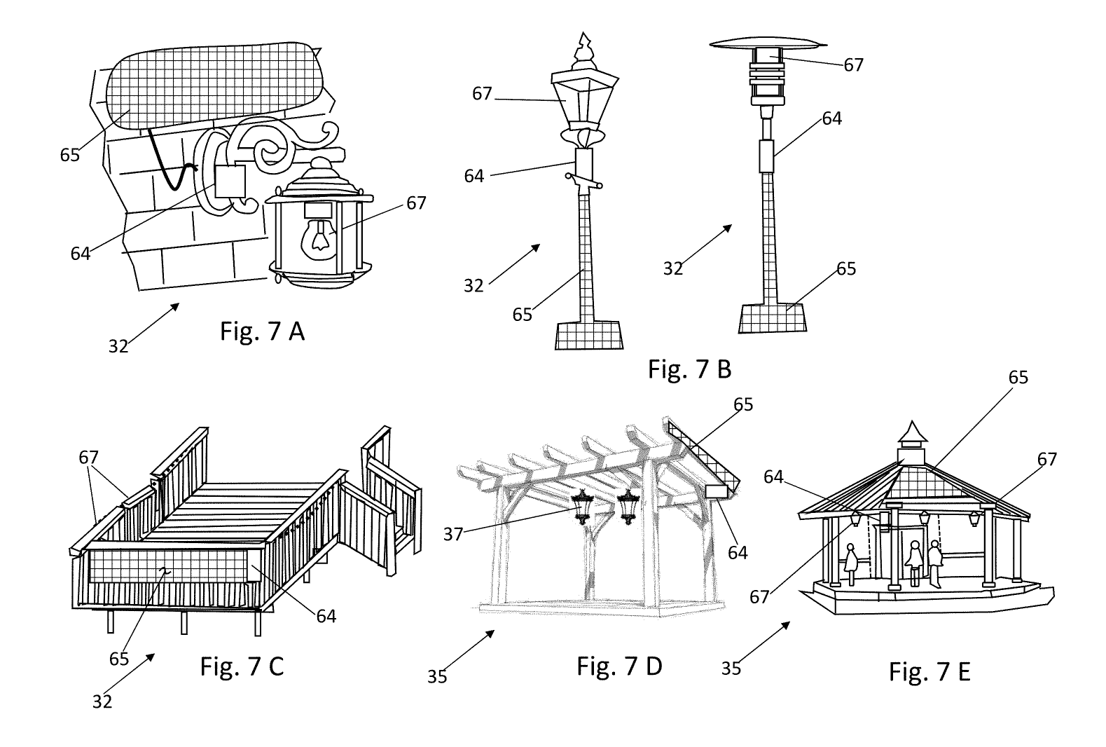

FIGS. 7 A through 7 E are sketches of other uses of the Flexible solar panel system built into Existing Products such as yard lights and structures with desired lighting. Viewed here are: a flexible thin photovoltaic solar panel system 32 built into an porch or yard lamp or small plants and trees; a flexible thin photovoltaic solar panel system 35 built into structures needing lights such as decks, gazebos and pergolas; an individual battery 64 at palm tree, light, decoration etc.; a flexible thin photovoltaic solar bands (for larger installations and greater requirements) 65 such as amorphous thin-film silicon (a-Si), cadmium telluride (CdTe), and copper indium gallium di-selenide (CIGS), and other photovoltaic, flexible and composite materials as they become commercially feasible; and a light source 67 such as, for example and not limitation, light emitting diodes (LED), fluorescent, incandescent, halogen, mercury vapor, etc.

With this description it is to be understood that the Flexible solar panel system 30 built into Existing Products and into recycled materials is not to be limited to only the disclosed embodiment of product. The features of the solar system 30 are intended to cover various modifications and equivalent arrangements included within the spirit and scope of the description.

While certain novel features of this invention have been shown and described and are pointed out in the annexed claims, it is not intended to be limited to the details above, since it will be understood that various omissions, modifications, substitutions and changes in the forms and details of the device illustrated and in its operation can be made by those skilled in the art without departing in any way from the spirit of the present invention. Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

Unless defined otherwise, all technical and scientific terms used herein have the same meaning as commonly understood by one of ordinary skill in the art to which these inventions belong. Although any methods and materials similar or equivalent to those described herein can also be used in the practice or testing of the present inventions, the preferred methods and materials are now described above in the foregoing paragraphs.

Other embodiments of the invention are possible. Although the description above contains much specificity, these should not be construed as limiting the scope of the invention, but as merely providing illustrations of some of the presently preferred embodiments of this invention. It is also contemplated that various combinations or sub-combinations of the specific features and aspects of the embodiments may be made and still fall within the scope of the inventions. It should be understood that various features and aspects of the disclosed embodiments can be combined with or substituted for one another in order to form varying modes of the disclosed inventions. Thus, it is intended that the scope of at least some of the present inventions herein disclosed should not be limited by the particular disclosed embodiments described above.

The terms recited in the claims should be given their ordinary and customary meaning as determined by reference to relevant entries (e.g., definition of “plane” as a carpenter's tool would not be relevant to the use of the term “plane” when used to refer to an airplane, etc.) in dictionaries (e.g., widely used general reference dictionaries and/or relevant technical dictionaries), commonly understood meanings by those in the art, etc., with the understanding that the broadest meaning imparted by any one or combination of these sources should be given to the claim terms (e.g., two or more relevant dictionary entries should be combined to provide the broadest meaning of the combination of entries, etc.) subject only to the following exceptions: (a) if a term is used herein in a manner more expansive than its ordinary and customary meaning, the term should be given its ordinary and customary meaning plus the additional expansive meaning, or (b) if a term has been explicitly defined to have a different meaning by reciting the term followed by the phrase “as used herein shall mean” or similar language (e.g., “herein this term means,” “as defined herein,” “for the purposes of this disclosure [the term] shall mean,” etc.). References to specific examples, use of “i.e.,” use of the word “invention,” etc., are not meant to invoke exception (b) or otherwise restrict the scope of the recited claim terms. Other than situations where exception (b) applies, nothing contained herein should be considered a disclaimer or disavowal of claim scope. Accordingly, the subject matter recited in the claims is not coextensive with and should not be interpreted to be coextensive with any particular embodiment, feature, or combination of features shown herein. This is true even if only a single embodiment of the particular feature or combination of features is illustrated and described herein. Thus, the appended claims should be read to be given their broadest interpretation in view of the prior art and the ordinary meaning of the claim terms.

Unless otherwise indicated, all numbers or expressions, such as those expressing dimensions, physical characteristics, etc. used in the specification (other than the claims) are understood as modified in all instances by the term “approximately.” At the very least, and not as an attempt to limit the application of the doctrine of equivalents to the claims, each numerical parameter recited in the specification or claims which is modified by the term “approximately” should at least be construed in light of the number of recited significant digits and by applying ordinary rounding techniques.

The present invention contemplates modifications as would occur to those skilled in the art. While the disclosure has been illustrated and described in detail in the figures and the foregoing description, the same is to be considered as illustrative and not restrictive in character, it being understood that only selected embodiments have been shown and described and that all changes, modifications and equivalents that come within the spirit of the disclosures described heretofore and or/defined by the following claims are desired to be protected.

What is claimed is:

1. A flexible solar panel system built into a group of existing products by using durable recycled materials, the system is comprised of:
(a) a flexible photo voltaic solar cell and energy collector, made of a durable material and used to produce electricity;
(b) a battery to store the electric power;
(c) a light source;
(d) a first conductor connected at one end to the solar cell and the other end connected to the battery;
(e) a second conductor connected at one end to the light source and the other end connected to the battery; and
(f) a structure as a means for supporting the solar cell, the battery, the light source, the first conductor and the second conductor
wherein the flexible solar panel system provides renewable energy to be used with different devices.

2. The solar panel system in claim 1 further comprised of a voltage/charge meter and a means for connecting connection system to connect/integrate the solar panel system to an electrical power grid.

3. The solar panel system in claim wherein the means for supporting structure is a structure selected from a group consisting of an artificial palm tree, a porch light, a yard lamp, small artificial plants/flora, artificial trees, an array of palm trees, an artificial vegetation, an outdoor Christmas decoration, a set of outdoor decorations, a deck, a gazebo, a pergola, and an array of artificial palm trees at a residential development.

4. The solar panel system in claim 1 wherein the structure is an artificial palm tree.

5. The solar panel system in claim 4 wherein the artificial palm tree is manufactured from a group consisting of used tires, used plastic, used composite materials, used paper, non-biodegradable material, and used cardboard pulp.

6. The flexible solar panel system in claim 1 wherein the durable material of the flexible photo voltaic solar cell and energy collector is selected from a group consisting of amorphous thin-film silicon (a-Si), cadmium telluride (CdTe), and copper indium gallium di-selenide (CIGS).

7. A flexible solar panel system built into a group of existing products by using durable recycled materials, the system is comprised of:
(a) a flexible photo voltaic solar cell and energy collector, made of a durable material and used to produce electricity;
(b) a battery to store the electric power;
(c) a light source;
(d) a first conductor connected at one end to the solar cell and the other end connected to the battery;
(e) a second conductor connected at one end to the light source and the other end connected to the battery; and
(f) an artificial palm tree as a structure for supporting the solar cell, the battery, the light source, the first conductor and the second conductor
wherein the flexible solar panel system provides renewable energy to be used with different devices.

8. The solar panel system in claim 7 wherein the artificial palm tree is manufactured from a group consisting of used tires, used plastic, used composite materials, used paper, and used cardboard pulp.

9. The solar panel system in claim 7 further comprised of a voltage/charge meter and a means for connecting connection system to connect/integrate the solar panel system to an electrical power grid.

10. The flexible solar panel system in claim 7 wherein the durable material of the flexible photo voltaic solar cell and energy collector is selected from a group consisting of amorphous thin-film silicon (a-Si), cadmium telluride (CdTe), and copper indium gallium di-selenide (CIGS).
